(19) United States
(12) Patent Application Publication
(10) Pub. No.: US 2011/0244617 A1
(43) Pub. Date: Oct. 6, 2011

(54) FORMING A COMPOUND-NITRIDE STRUCTURE THAT INCLUDES A NUCLEATION LAYER

(75) Inventor: Jie Su, Santa Clara, CA (US)

(73) Assignee: Applied Materials, Inc., Santa Clara, CA (US)

(21) Appl. No.: 13/052,861

(22) Filed: Mar. 21, 2011

Related U.S. Application Data
(60) Provisional application No. 61/320,234, filed on Apr. 1, 2010.

(51) Int. Cl. H01L 33/02

(52) U.S. Cl. 438/46; 257/E33.023

(57) ABSTRACT

The present invention generally provides apparatus and methods for forming LED structures. In one embodiment where a sapphire substrate is selected, the growth of bulk Group III-nitrides may be deposited in a HVPE or MOCVD chamber while a separate processing chamber, such as a PVD, MOCVD, CVD, or ALD chamber, may be used to grow buffer layers on the sapphire substrate at lower growth rate. The buffer layer may be GaN, AlN, AlGaN, InGaN, or InAlGaN. In another embodiment where a silicon-based substrate is selected, the growth of bulk Group III-nitrides may be deposited in a HVPE or MOCVD chamber in which an Al-free environment is provided while a separate processing chamber with a Ga-free environment is used to grow a Ga-free buffer layer, such as Al, AlN, or SiN, on the silicon-based substrate. The separate processing chamber may be a PVD, CVD, MOCVD, a plasma assisted MOCVD, or other vapor phase deposition techniques.

### CROSS-REFERENCE TO RELATED APPLICATIONS

This application claims benefit of U.S. provisional patent application Ser. No. 61/320,234 [Attorney Docket No.: APPM 14823L], filed Apr. 1, 2010, which is herein incorporated by reference.

### BACKGROUND OF THE INVENTION

1. Field of the Invention

Embodiments of the present invention generally relate to the manufacturing of devices, such as light emitting diodes (LEDs), laser diodes (LDs) and, more particularly, to processes for forming Group III-V materials.

2. Description of the Related Art

Group III-V materials are finding greater importance in the development and fabrication of a variety of semiconductor devices, such as short wavelength LEDs, LDs, and electronic devices including high power, high frequency, high temperature transistors and integrated circuits. For example, short wavelength (e.g., blue/green to ultraviolet) LEDs are fabricated using the Group III-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, comprising Group II-VI elements.

One method that has been used for depositing Group III-nitrides, such as GaN, is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursor gases react at the surface of the heated substrate to form a Group III-nitride layer, such as GaN, on the substrate surface. The quality of the film depends in part upon deposition uniformity which, in turn, depends upon uniform flow and mixing of the precursors across the substrate.

While the feasibility of using GaN to create photoluminescence in the blue region of the spectrum has been known for decades, there were numerous barriers that impeded their practical fabrication. For example, material differences between the sapphire substrate and Group III-nitride layers, such as the lattice constant, thermal expansion coefficient, and interfacial surface energy, may create dislocations that may propagate through the structure and degrade the device performance, due to the induced stress created by the lattice mismatch between the sapphire substrate and Group III-nitride layers. Various types of buffer layers have been used in between the substrate and the Group III-nitride layer to modify the surface energy of the underlying substrate, alleviate the intrinsic stress within the lattice-matched nitride layers, and provide nucleation sites for epitaxial growth of the subsequent layers. However, the quality of conventional Group III-nitrides is generally not satisfactory because the film properties, such as thickness, island density, island size, etc. of the buffer layer are not always consistent. Any slight changes in growth parameters during the nucleation could easily affect the nitride layer quality, which in turn leads to twist or mis-alignment of nucleation islands before the coalescence, thereby adversely affecting the growth of the bulk Group III nitrides.

As the demand for LEDs, LDs, transistors, and integrated circuits increases, the task of depositing high quality Group III-nitride films takes on greater importance. Therefore, there is a need for a process and apparatus that can improve the quality of the buffer layer and the growth of Group III nitrides over the substrate.

### SUMMARY OF THE INVENTION

In one embodiment, a method for fabricating a compound nitride-based semiconductor structure is provided. The method comprises forming a Group III-nitride buffer layer over one or more substrates in a first processing chamber, transferring the one or more substrates having the Group III-nitride buffer layer deposited thereon into a second processing chamber without exposing the one or more substrates to an ambient atmospheric environment to form a first Group III-nitride layer over the buffer layer, forming an InGaN multi-quantum-well (MQW) active layer over the Group III-nitride buffer layer in a third processing chamber, forming a p-AlGaN layer on the InGaN MQW active layer in a fourth processing chamber, and forming a second Group III-nitride layer over the p-AlGaN layer. The Group III-nitride buffer layer may be GaN, AlN, AlGaN, InGaN, or InAlGaN, and be undoped or doped with an n-type or p-type dopant element, depending upon the application. The first processing chamber may be a PVD, MOCVD, CVD, ALD, or any other type of similar deposition chamber. The second processing chamber may be a MOCVD or HVPE chamber. The third processing chamber may be a MOCVD chamber. The fourth processing chamber may be a MOCVD or HVPE chamber.

In another embodiment, a method for fabricating a compound nitride-based semiconductor structure is provided. The method comprises forming a buffer layer over one or more silicon-based substrates in a first processing chamber containing a Ga-free environment, transferring the one or more silicon-based substrates having the buffer layer deposited thereon, without exposing the one or more substrates to an ambient atmospheric environment, into a second processing chamber containing an Al-free environment to form a bulk Group III-V layer over the buffer layer in the second processing chamber. In one example, the buffer layer may include at least one of Al, AlN, or SiN, which may be undoped or doped with an n-type or p-type dopant element depending upon the application. The first processing chamber may be a MOCVD, PVD, CVD, ALD chamber, or any other type of deposition chamber. The second processing chamber may be a MOCVD or HVPE chamber. In another example, a passivation layer comprising Al, AlN, or SiN may be deposited on the surface of the silicon-based substrate followed by a GaN buffer layer, which may be undoped or doped with an n-type or p-type dopant element depending upon the application. The passivation layer and the buffer layer may be deposited in the same or different processing chamber.

In one another embodiment, a processing system for processing compound nitride-based semiconductor devices is provided. The processing system comprises a first processing chamber configured to deposit a buffer layer on a surface of one or more substrates, a first substrate handling system configured to transfer the one or more substrates from an input region to the first processing chamber, a second processing chamber configured to deposit one or more Group III-V layers over the buffer layer formed on the one or more substrates, and an automatic transferring system configured to transfer the one or more substrates between the first processing chamber and the second processing chamber without exposing the one or more substrates to an ambient atmospheric environment. In one example, the first processing chamber may be a MOCVD, PVD, CVD, ALD chamber, or any other vapor deposition chamber. The second processing chamber may be a MOCVD or HVPE chamber.

In yet another embodiment, an integrated processing system for processing compound nitride-based semiconductor devices is provided. The integrated processing system comprises a transfer region, a robot assembly disposed in the transfer region for transferring one or more substrates without exposing the one or more substrates to an ambient atmospheric environment, a vapor phase deposition chamber in transferable communication with the transfer region and configured to form a buffer layer over the one or more substrates, a hydride vapor phase epitaxial (HVPE) chamber in transferable communication with the transfer region and configured to form an n-doped and/or p-doped gallium nitride (GaN) layer over the one or more substrates, and a metal organic chemical vapor deposition (MOCVD) chamber in transferable communication with the transfer region and configured to form an InGaN layer between the n-doped and p-doped GaN layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a structure of an exemplary GaN-based light emitting diodes (LEDs).

FIG. 2 is a schematic top view illustrating one embodiment of a processing system for fabricating compound nitride semiconductor devices according to embodiments of the invention described herein.

FIG. 3 is a schematic cross-sectional view of a metal-organic chemical vapor deposition (MOCVD) chamber for fabricating compound nitride semiconductor devices according to embodiments of the invention described herein.

FIG. 4A is a schematic isometric view of a hydride vapor phase epitaxy (HVPE) chamber for fabricating compound nitride semiconductor devices according to embodiments of the invention.

FIG. 4B is a schematic cross-sectional view of a HVPE chamber for fabricating compound nitride semiconductor devices according to embodiments of the invention.

FIG. 5 is a flow diagram of a processing sequence in accordance with one embodiment of the present invention.

FIG. 6 is a flow diagram of a processing sequence in accordance with another embodiment of the present invention.

### DETAILED DESCRIPTION

Embodiments of the invention described herein generally relate to methods for forming Group III-V materials using a metal organic chemical vapor deposition (MOCVD), hydride vapor phase epitaxial (HVPE), physical vapor deposition (PVD), chemical vapor deposition (CVD), and/or atomic layer deposition (ALD) processes. In one embodiment, where a sapphire substrate is chosen, the growth of thick Group III-nitrides may be deposited in a HVPE or MOCVD chamber while a separate processing chamber, such as a PVD, MOCVD, CVD, or ALD chamber, may be used to grow buffer layers, or sometimes referred to as nucleation layers, on the sapphire substrate at a lower growth rate. The buffer layer may be GaN, AlN, AlGaN, InGaN or InAlGaN, which may be doped or undoped.

In another embodiment where a silicon-based substrate is selected, the growth of thick Group III-nitrides may be deposited in an HVPE or MOCVD chamber in which an Al-free environment is provided, while a separate processing chamber with a Ga-free environment is used to grow a Ga-free buffer layer, such as Al, AlN, or SiN, between the Group III-nitride layer and the silicon-based substrate. In such an embodiment, the separate processing chamber may use a PVD, CVD, MOCVD, plasma assisted MOCVD, or other similar vapor phase deposition technique to deposit the Ga-free buffer layer. A dedicated processing chamber is believed to help improve film properties of the buffer layer, since growth characteristics of the buffer layer, such as island density, island size, thickness, etc. are better controlled, which in turn leads to a better integration between the silicon-based substrate and Group III-nitride layers deposited thereover. Also, the throughput of a system containing these separate chambers will be increased over a convention single chamber design, due to the elimination of the need for the increased number of cleaning and process adjustments that would otherwise be required if the buffer layer and bulk Group III nitride layers are formed in the same chamber.

### Exemplary Hardware

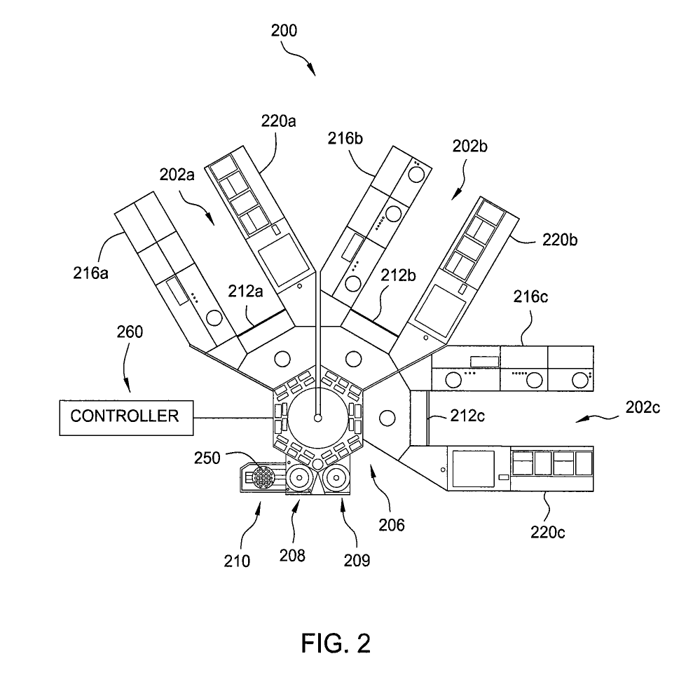

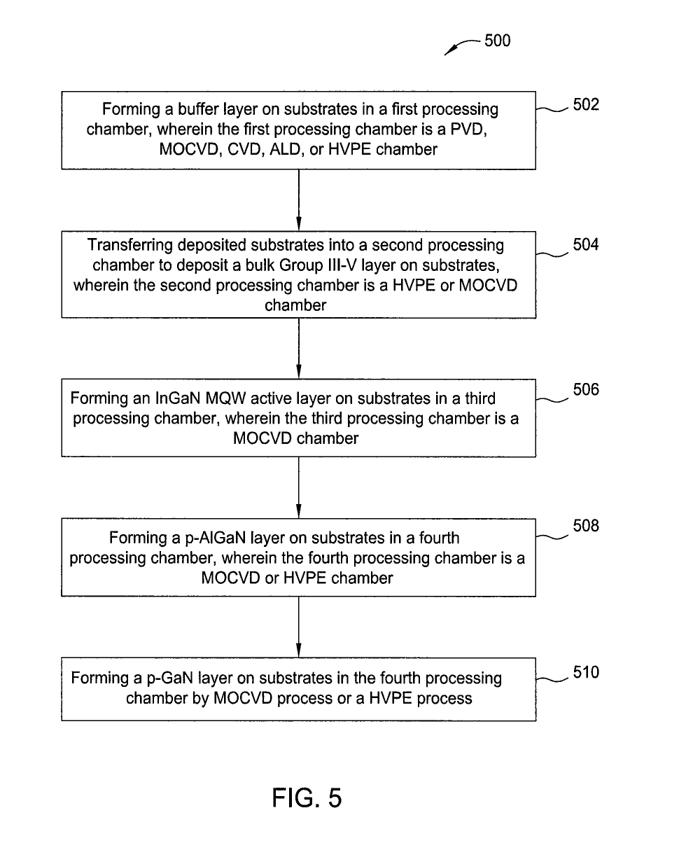

FIG. 2 is a schematic top view of an exemplary processing system 200 that may be used for fabricating compound nitride semiconductor devices according to at least one embodiment of the invention. It is contemplated that the processes described below with respect to FIG. 5 may be also preformed in other suitable processing chambers. The environment within the processing system 200 may be maintained in a vacuum state, or at a pressure below atmospheric pressure. In certain embodiments it may be desirable to backfill the processing system 200 with an inert gas such as nitrogen.

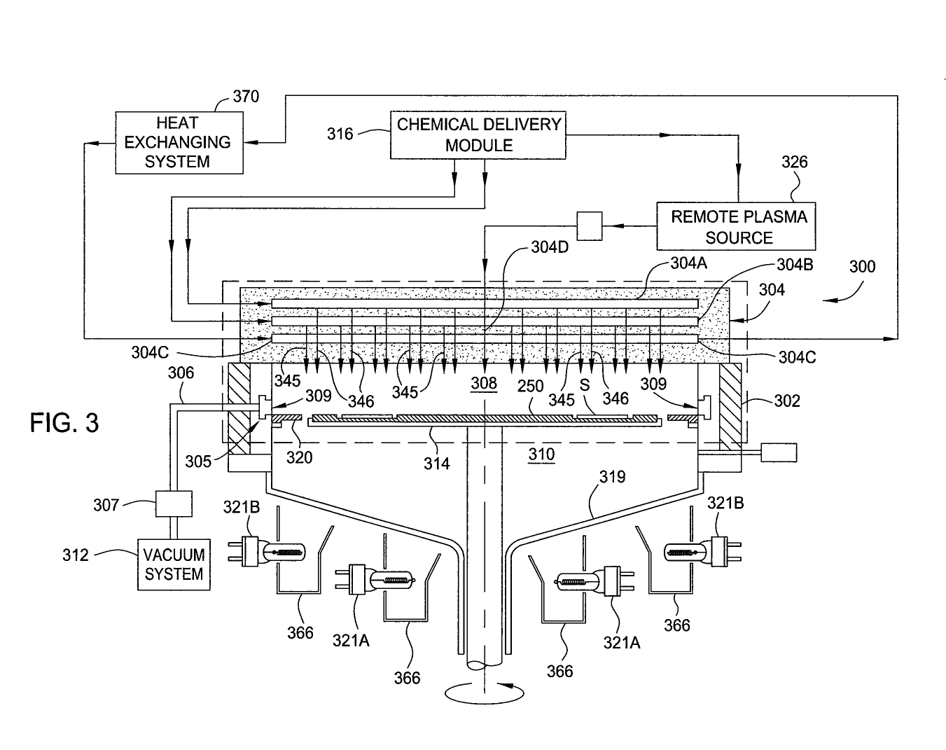

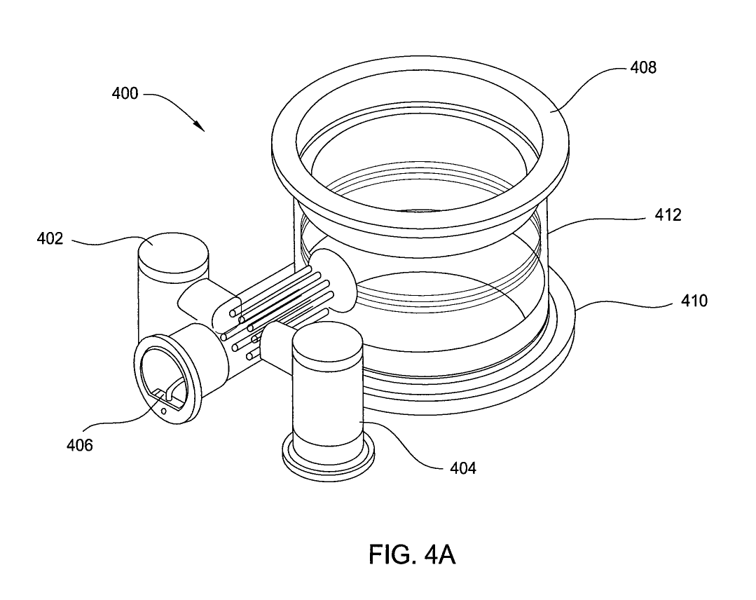

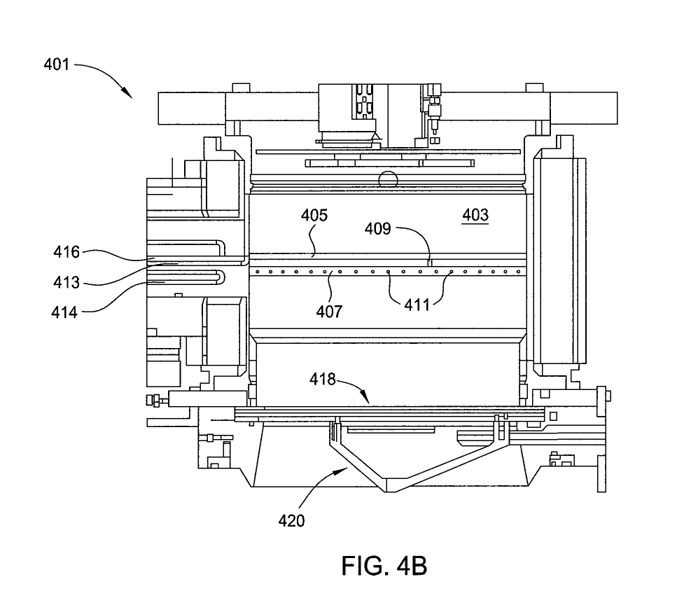

The processing system 200 generally includes a transfer chamber 206 housing a substrate handler (not shown), a first MOCVD chamber 202a, a second MOCVD chamber 202b, and a third MOCVD chamber 202c coupled with the transfer chamber 206, a loadlock chamber 208 coupled with the transfer chamber 206, a batch loadlock chamber 209, for storing substrates, coupled with the transfer chamber 206, and a load station 210, for loading substrates, coupled with the loadlock chamber 208. The transfer chamber 206 comprises a robot assembly (not shown) operable to pick up and transfer substrates between the loadlock chamber 208, the batch loadlock chamber 209, and the MOCVD chambers 202a-c. Although three MOCVD chambers 202a, 202b, 202c are shown, it should be understood that any number of MOCVD chambers may be coupled with the transfer chamber 206. Additionally, chambers 202a, 202b, 202c may be combinations of one or more MOCVD chambers (such as the MOCVD chamber 300 shown in FIG. 3, described below) with one or more Hydride Vapor Phase Epitaxial (HVPE) chambers (such as 400, 401 shown in FIGS. 4A and 4B) coupled with the transfer chamber 206. Alternatively, the processing system 200 may be an in-line system without a transfer chamber. In various embodiments, a PVD, CVD, or ALD chamber may be additionally included or replaced with one of the MOCVD or HVPE chambers coupled to the transfer chamber 206 upon application.

Each MOCVD chamber 202a, 202b, 202c generally includes a chamber body 212a, 212b, 212c forming a processing region where a substrate is placed to undergo processing, a chemical delivery module 216a, 216b, 216c from which gas precursors are delivered to the chamber body 212a, 212b, 212c, and an electrical module 220a, 220b, 220c for each MOCVD chamber 202a, 202b, 202c that includes the electrical system for each MOCVD chamber of the processing system 200. Each MOCVD chamber 202a, 202b, 202c is adapted to perform CVD processes in which, for example, metalorganic elements react with metal hydride elements to form thin layers of compound nitride semiconductor materials.

The transfer chamber 206 may remain under vacuum or at a pressure below atmospheric pressure during processing. The vacuum level of the transfer chamber 206 may be adjusted to match the vacuum level of the MOCVD chamber 202a. For example, when transferring a substrate from the transfer chamber 206 into the MOCVD chamber 202a (or vice versa), the transfer chamber 206 and the MOCVD chamber 202a may be maintained at the same vacuum level. Then, when transferring a substrate from the transfer chamber 206 to the loadlock chamber 208 or batch loadlock chamber 209 (or vice versa), the transfer chamber vacuum level may match the vacuum level of the loadlock chamber 208 or batch loadlock chamber 209 even through the vacuum level of the loadlock chamber 208 or batch loadlock chamber 209 and the MOCVD chamber 202a may be different. In certain embodiments it may be desirable to backfill the transfer chamber 206 with an inert gas such as nitrogen. For example, the substrate may be transferred in an environment having greater than 90% N₂ or NH₃. Alternatively, the substrate may be transferred in a high purity H₂ environment, such as in an environment having greater than 90% H₂.

In the processing system 200, the robot assembly transfers a carrier plate 250 loaded with one or more substrates into the first MOCVD chamber 202a to undergo a first deposition process. The carrier plate may range from 200 mm-750 mm. The substrate carrier may be formed from a variety of materials, including SiC or SiC-coated graphite. In one embodiment, the carrier plate 250 comprises a silicon carbide material and has a surface area of about 1,000 cm² or more, preferably 2,000 cm² or more, and more preferably 4,000 cm² or more. Exemplary embodiments of the carrier plate are further described in U.S. patent application Ser. No. 12/871,143, filed Aug. 28, 2009, entitled “WAFER CARRIER DESIGN FOR IMPROVED PHOTOLUMINESCENCE UNIFORMITY”. The robot assembly transfers the carrier plate 250 into the second MOCVD chamber 202b to undergo a second deposition process. The robot assembly transfers the carrier plate 250 into either the first MOCVD chamber 202a or the third MOCVD chamber 202c to undergo a third deposition process. After all or some of the deposition steps have been completed, the carrier plate 250 is transferred from the MOCVD chamber 202a-202c back to the loadlock chamber 208. The carrier plate 250 is then transferred to the load station 210. Alternatively, the carrier plate 250 may be stored in either the loadlock chamber 208 or the batch loadlock chamber 209 prior to further processing in one or more of the MOCVD chambers 202a-202c. One exemplary system is described in U.S. patent application Ser. No. 12/023,572, filed Jan. 31, 2008, entitled “PROCESSING SYSTEM FOR FABRICATING COMPOUND NITRIDE SEMICONDUCTOR DEVICES,” which is hereby incorporated by reference in its entirety.

A system controller 260 controls activities and operating parameters of the processing system 200. The system controller 260 includes a computer processor, support circuits and a computer-readable memory coupled to the processor. The processor executes system control software, such as a computer program stored in memory. Aspects of the processing system and methods of use are further described in U.S. patent application Ser. No. 11/404,516, filed Apr. 14, 2006, now published as U.S. 2007/024516, entitled “EPITAXIAL GROWTH OF COMPOUND NITRIDE STRUCTURES,” which is hereby incorporated by reference in its entirety.

### Exemplary MOCVD Chamber

FIG. 3 is a schematic cross-sectional view of an MOCVD chamber 300 that may be used for fabricating compound nitride semiconductor devices according to at least one embodiment of the invention. The MOCVD chamber 300 may be one or more of the chambers 202a, 202b or 202c, as described above with reference to system 200. The MOCVD chamber 300 generally includes a chamber body 302, a chemical delivery module 316 for delivering precursor gases, carrier gases, cleaning gases, and/or purge gases, a remote plasma system 326 with a plasma source, a susceptor or substrate support 314, and a vacuum system 312. The chamber body 302 of the MOCVD chamber 300 encloses a processing region 308. A showerhead assembly 304 is disposed at one end of the processing region 308, and a carrier plate 250 is disposed at the other end of the processing region 308. The carrier plate 250 may be disposed on the substrate support 314.

In one embodiment, the showerhead assembly 304 may be a dual-zone assembly having a first processing gas channel 304A coupled with the chemical delivery module 316 for delivering a first precursor or first process gas mixture to the processing region 308, a second processing gas channel 304B coupled with the chemical delivery module 316 for delivering a second precursor or second process gas mixture to the processing region 308 and a temperature control channel 304C coupled with a heat exchanging system 370 for flowing a heat exchanging fluid to the showerhead assembly 304 to help regulate the temperature of the showerhead assembly 304. Suitable heat exchanging fluids may include water, water-based ethylene glycol mixtures, a perfluoropolyether (e.g. Galden® fluid), oil-based thermal transfer fluids, or similar fluids.

During processing the first precursor or first process gas mixture may be delivered to the processing region 308 via gas conduits 346 coupled with the first processing gas channel 304A in the showerhead assembly 304 and the second precursor or second process gas mixture may be delivered to the processing region 308 via gas conduits 345 coupled with the second processing gas channel 304B in the showerhead assembly 304. The process gas mixtures or precursors may include one or more precursor gases or process gases, as well as carrier gases and/or dopant gases, which may be mixed with precursor gases. Exemplary showerheads that may be adapted to practice embodiments described herein are described in U.S. patent application Ser. No. 11/873,132, filed Oct. 16, 2007, entitled “MULTI-GAS STRAIGHT CHANNEL SHOWERHEAD,” U.S. patent application Ser. No. 11/873,141, filed Oct. 16, 2007, now published as U.S. 2009-0095222, entitled “MULTI-GAS SPIRAL CHANNEL SHOWERHEAD,” and U.S. patent application Ser. No. 11/873,170, filed Oct. 16, 2007, now published as U.S. 2009-0095221, entitled “MULTI-GAS CONCENTRIC INJECTION SHOWERHEAD,” all of which are incorporated by reference in their entireties.

A lower dome 319 is disposed at one end of a lower volume 310, and the carrier plate 250 is disposed at the other end of the lower volume 310. The carrier plate 250 is shown in process position, but may be moved to a lower position where, for example, the substrates S may be loaded or unloaded. An exhaust ring 320 may be disposed around the periphery of the carrier plate 250 to help prevent deposition from occurring in the lower volume 310 and also help direct exhaust gases from the MOCVD chamber 300 to exhaust ports 309. The lower dome 319 may be made of transparent material, such as high-purity quartz, to allow light to pass through for radiant heating of the substrates S. The radiant heating may be provided by a plurality of inner lamps 321A and outer lamps 321 B disposed below the lower dome 319 and reflectors 366 may be used to help control the MOCVD chamber 300 exposure to the radiant energy provided by inner and outer lamps 321A and 321B. Additional rings of lamps may also be used for finer temperature control of the substrates S.

A purge gas (e.g., a nitrogen containing gas) may be delivered into the MOCVD chamber 300 from the showerhead assembly 304 and/or from inlet ports or tubes (not shown) disposed below the carrier plate 250 and near the bottom of the chamber body. The purge gas enters the lower volume 310 of the MOCVD chamber 300 and flows upwards past the carrier plate 250 and exhaust ring 320 and into multiple exhaust ports 309 which are disposed around an annular exhaust channel 305. An exhaust conduit 306 connects the annular exhaust channel 305 to a vacuum system 312 which includes a vacuum pump 307. The MOCVD chamber 300 pressure may be controlled using a valve system which controls the rate at which the exhaust gases are drawn from the annular exhaust channel. Other aspects of the MOCVD chamber are described in U.S. patent application Ser. No. 12/023,520, filed Jan. 31, 2008, entitled “CVD APPARATUS,” which is herein incorporated by reference in its entirety.

If desired, a cleaning gas (e.g., a halogen containing gas, such as chlorine gas) may be delivered into the MOCVD chamber 300 from the showerhead assembly 304 and/or from inlet ports or tubes (not shown) disposed near the processing region 308. The cleaning gas enters the processing region 308 of the MOCVD chamber 300 to remove deposits from chamber components such as the substrate support 314 and the showerhead assembly 304 and exits the MOCVD chamber 300 via multiple exhaust ports 309 which are disposed around the annular exhaust channel 305.

The chemical delivery module 316 generally supplies precursors and/or chemicals to the MOCVD chamber 300. Reactive gases, carrier gases, purge gases, and cleaning gases are supplied from the chemical delivery module 316 through supply lines and into the chamber 300. The gases may be supplied through supply lines and into a gas mixing box, where they are mixed together and delivered to showerhead assembly 304. Depending upon the process scheme, some of the precursor and/or chemicals delivered to the MOCVD chamber 300 may be liquid rather than gas. When liquid chemicals are used, the chemical delivery module includes a liquid injection system or other appropriate mechanism (e.g. a bubbler or vaporizer) to vaporize the liquid. Vapor from the liquids may be mixed with a carrier gas.

Remote plasma system 326 can produce a plasma for selected applications, such as chamber cleaning or etching residue or defective layers from a process substrate. Plasma species produced in the remote plasma system 326 from precursors supplied via an input line are sent via a conduit 304D for dispersion through the showerhead assembly 304 to the processing region 308 in the MOCVD chamber 300. Precursor gases for a cleaning application may include chlorine containing gases, fluorine containing gases, iodine containing gases, bromine containing gases, nitrogen containing gases, and/or other suitable reactive elements. Remote plasma system 326 may also be adapted to deposit CVD layers by flowing appropriate deposition precursor gases into remote plasma system 326 during a layer deposition process. In one example, the remote plasma system 326 is used to deliver active nitrogen species to the processing region 308.

The temperature of the walls of the MOCVD chamber 300 and surrounding structures, such as the exhaust passageway, may be further controlled by circulating a heat-exchange liquid through channels (not shown) in the walls of the chamber to form a heat exchanger. The showerhead assembly 304 may also have heat exchanging passages (not shown) to form an additional heat exchanger. Typical heat-exchange fluids include water-based ethylene glycol mixtures, oil-based thermal transfer fluids, or similar fluids. The heating of the showerhead assembly 304 may be performed using additional heat exchanger(s) that can reduce or eliminate condensation of undesirable reactant products and improve the elimination of volatile products of the process gases and other contaminants that might contaminate the process if they were to condense on the walls of the exhaust conduit 306 and migrate back into the processing chamber during periods of no gas flow.

### Exemplary HVPE Chamber

FIG. 4A is a schematic isometric view of a hydride vapor phase epitaxy (HVPE) chamber 400 for fabricating compound nitride semiconductor devices according to embodiments of the invention. The HVPE chamber 400 includes a first precursor source 402, a second precursor source 404, a passageway 406 for a reactive gas such as a chlorine containing gas to pass, an upper ring 408, a lower ring 410, and sidewalls 412. The chlorine containing gas may react with the precursor source such as gallium or aluminum to form a chloride.

FIG. 4B is a schematic cross-sectional view of a HVPE chamber 401 for fabricating compound nitride semiconductor devices according to embodiments of the invention. The HVPE chamber 401 includes a susceptor 418 supported by a support shaft 420. The HVPE chamber 401 also includes a chamber wall 403 having a first tube 405 coupled thereto. The first tube 405 is the tube into which the chloride reaction product initially flows before being released into the chamber. The tube 405 is coupled to a second tube 407 via one or more connectors 409. In one embodiment, the one or more connectors 409 may be arranged to substantially balance the flow of the chloride reaction product. In one embodiment, a plurality of connectors 409 may be present that are substantially identical. In another embodiment, a plurality of connectors 409 may be present in which at least one connector 409 is different from at least one other connector 409. In another embodiment, a plurality of connectors 409 may be present that are substantially uniformly distributed between the tubes 405, 407. In another embodiment, a plurality of connectors 409 may be present that are non-uniformly distributed between the tubes 405, 407. The tube 407 has a plurality of openings 411 therethrough to permit the chloride reaction product to enter into the processing space. In one embodiment, the openings 411 may be evenly distributed along the second tube 407. In another embodiment, the openings 411 may be non-uniformly distributed along the second tube 407. In one embodiment, the openings 411 may have a substantially similar size. In another embodiment, the openings 411 may have different sizes. In one embodiment, the openings 411 may face in a direction away from the substrate. In another embodiment, the openings 411 may face in a direction generally towards the substrate. In another embodiment, the openings 411 may face in a direction substantially parallel to the deposition surface of the substrate. In another embodiment, the openings 411 may face in multiple directions. The chloride gas is formed by initially introducing a chlorine containing gas into the precursor source or boat and flowed within the passage 416. The chlorine containing gas snakes around in the passage within tubes 414. The passage 416 is heated by the resistive heaters described above. Thus, the chlorine containing gas increases in temperature before coming into contact with the precursor. Once the chlorine comes into contact with the precursor, a reaction takes place to form a chloride reaction product that is flowed through the passage 416 in gas feed 413 that is coupled to the tube 414. Then, the chloride reaction product is evenly distributed and then disposed into the HVPE chamber 401. Other aspects of the HVPE chamber 401 are described in U.S. patent application Ser. No. 12/637,019, filed Dec. 15, 2009, entitled “HVPE CHAMBER HARDWARE,” which is herein incorporated by reference in its entirety.

### Exemplary Methods for Growth of Buffer Layer in a Separate Chamber

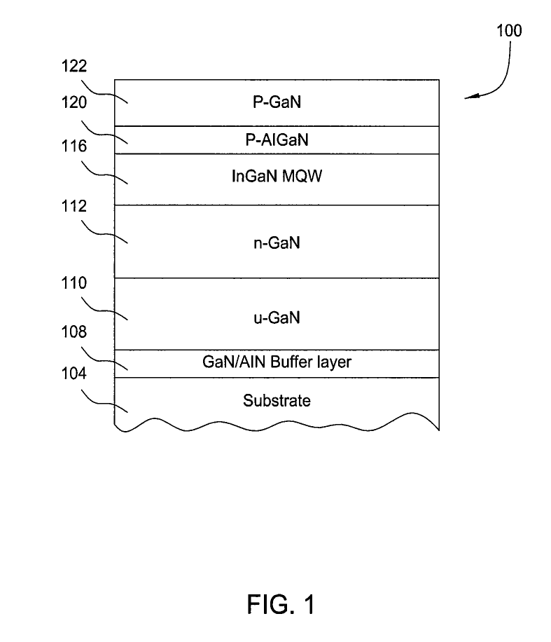

FIG. 1 shows an exemplary Group III-V device that may be made using various embodiments of the present invention. As illustrated in FIG. 1, a nitride-based LED structure 100 can be formed over a substrate 104, for example a (0001) sapphire substrate. Substrate size may range from 50 mm-200 mm in diameter or larger. An undoped GaN (u-GaN) layer 110 and an n-type GaN (n-GaN) layer 112 are sequentially deposited over a buffer layer 108 (such as GaN or AlN buffer layer) formed over the substrate 104. An active region of the device is embodied in a multi-quantum-well (MQW) active layer 116, shown in the drawing to comprise an InGaN layer. A p-n junction is formed with an overlying p-type AlGaN layer 120 acting as the electron blocking layer (EBL), with a p-type GaN contact layer 122 acting as a contact layer. While the discussion herein primarily refers to a LED type Group III-V device, this configuration is not intended to be limiting as to the scope of the invention described herein, since one or more of the processes described herein could be used to form other similar devices, such as laser diodes and Group III-V power conversion devices.

In the illustrated nitride-based LED structure 100 shown in FIG. 1, the substrate 104 may be any substrate which may include, but is not limited to sapphire (Al₂O₃), substantially pure silicon (Si), silicon carbide (SiC), spinel, zirconium oxide, as well as compound semiconductor substrates, such as gallium-arsenide (GaAs), lithium gallate, indium phosphate (InP), and single-crystal GaN among other substrates. In one embodiment, a sapphire substrate is used. To obtain improved growth characteristics of the Group III-nitrides deposited on the sapphire substrate, a novel processing sequence 500, which is illustrated in FIG. 5, is provided. It is contemplated that the number and sequence of steps are not intended to limiting as to the scope of the invention described herein, since one or more steps can be added, deleted and/or reordered without deviating from the basic scope of the invention described herein.

The processing sequence begins at step 502 by forming a buffer layer 108 on one or more substrates 104 (FIG. 1) in a first processing chamber. The substrates 104 may be cleaned in the first processing chamber using a cleaning gas or may have been previously cleaned prior to being transferred into the first processing chamber. The first processing chamber may be one of multiple processing chambers disposed in a processing system generally comprising a transfer chamber and a loadlock chamber, as discussed previously in detail in FIG. 2. Alternatively, the first processing chamber may be a batch processing chamber disposed in an in-line processing system with or without a transfer chamber. In either case, the first processing chamber may be a PVD, MOCVD, CVD, ALD chamber, or any other vapor deposition chamber. The buffer layer 108 may be a binary, ternary or quaternary film comprising a solid solution of one or more Group III elements and nitrogen. Buffer layer 108 can be any crystalline film which has a similar lattice structure (i.e., have the same cubic structure) with the Group III-Nitride crystalline film that is to be formed thereon. In various embodiments of the invention, the buffer layer 108 may be GaN, AlN, AlGaN, InGaN, or InAlGaN (undoped or doped with an n-type or p-type dopant element depending upon application), using, for example, MOCVD, HVPE, PVD, CVD, ALD, or any other suitable process. In one example, the buffer layer 108 is an AlN material deposited in a PVD chamber (not shown), which can be a stand-alone chamber, or be part of a cluster tool, as discussed above with respect to FIG. 2. In such a case, the AlN material may be deposited on the substrate by reactively sputtering the Al in an argon (Ar) and nitrogen (N₂) gas mixture that is maintained at a reduced pressure, such as an environment maintained at about 0.5 mTorr to several Torr, for example, about 2 mTorr to about 300 Torr. In another case, the AlN material may be deposited on the substrate by RF and/or DC biasing an aluminum nitride (AlN) target in an argon (Ar), and/or nitrogen (N₂), environment to sputter the AlN material on to the surface of the substrate. It is also contemplated that the AlN material may be deposited by evaporating aluminum (Al) in a nitorgen (N₂) rich environment, or even by forming the AlN layer using a CVD method. In various embodiments, the buffer layer 108 is formed to a thickness between 10-800 nm, but the thickness may vary and in some cases it could be up to 0.5-1.0 μm.

In an alternative example, the buffer layer 108 may be a GaN material formed in an MOCVD chamber 300 (FIG. 3) using an MOCVD process. The MOCVD process generally has slower deposition rates (e.g., 5 μm/hr or less) and provides highly uniform deposition results and better control on the growth rates. In addition, MOCVD nitride films are typically deposited at lower temperature, allowing the fabrication process to have a lower thermal budget. In this example, an organometallic precursor and a nitrogen containing precursor, such as ammonia (NH₃), is introduced into the first processing chamber to start deposition of the buffer layer 108. The organometallic precursor may include a Group III metal and a carbon group, among other constituents. For example, the precursor may include an alkyl Group III metal compound such as an alkyl aluminum compound, an alkyl gallium compound, and/or an alkyl indium compound, among others. Specific precursor examples may include, but are not limited to trimethylaluminum (TMA), triethyl-aluminum (TEA), trimethylindium (TMI), triethylindium (TED, trimethylgallium (TMG), and triethylgallium (TEG). Larger sized alkyl groups, such as propyl, pentyl, hexal, etc., may also be combined with the Group III metal. Different sized alkyl groups may also be combined in the same precursor, such as ethyldimetylgallium, methyldiethyl-aluminum, etc. Other organic moieties such as aromatic groups, alkene groups, alkyne groups, etc. may also be part of the organometallic precursor. If desired, the nitrogen containing precursor may flow in a separate gas stream into the first processing chamber and mix with the organometallic precursor gas stream in a space in the heated reaction zone above the substrate. Carrier gases such as helium may be used to facilitate the flow of the precursors in the first processing chamber, as well as adjust the total pressure in the chamber. The carrier gas may be premixed with the precursor gas before entering the chamber, and/or may enter the chamber in an unmixed state through a separate flow line.

In this alternative example using the MOCVD process, the buffer layer 108, such as a GaN buffer layer, is formed by introducing precursor gases, such as trimethyl gallium (TMG) and NH₃ into the first processing chamber at a TMG flow rate between about 0 sccm to about 10 sccm and a NH₃ flow rate between about 0 slm to about 30 slm, and a susceptor temperature of about 500° C. to about 900° C. and a chamber pressure of from about 50 Torr to about 300 Torr to form the GaN buffer layer with a thickness of between about 10 nm to about 50 nm. In embodiments where the buffer layer 108 comprises AlN, the precursor gases such as trimethyl aluminum (TMA) and NH₃ are introduced into the first processing chamber at a TMA flow rate between about 0 sccm to about 10 sccm and a NH₃ flow rate between about 0 slm to about 30 slm, and a susceptor temperature of about 500° C. to about 900° C. and a chamber pressure of from about 50 Torr to about 300 Torr to form the AlN buffer layer with a thickness of between about 10 nm to about 50 nm. Alternatively, the buffer layer 108 may be a GaN material formed using a HVPE chamber. In such case, the GaN buffer layer is rapidly formed on the substrate from precursors of gallium and nitrogen using a HVPE process.

At step 504, after deposition of the buffer layer 108, the deposited substrates are transferred into a second processing chamber to deposit bulk Group III-nitride layers over the buffer layer 108. The bulk Group III-nitride layers generally include undoped GaN (u-GaN) layer 110 and a n-doped (n-GaN) layer 112 sequentially deposited on the buffer layer 108, as shown in FIG. 1. The second processing chamber may be a MOCVD chamber (FIG. 3), a HVPE chamber (FIGS. 4A and 4B), or any other suitable processing chamber. In one example, the bulk Group III-nitride layers are deposited using a HVPE chamber.

In the case where an MOCVD process is used to deposit Group III-nitride layers, precursor gases such as TMG, NH₃, and N₂ may be introduced into the second processing chamber at a susceptor temperature of about 950° C. to about 1050° C. and a chamber pressure of about 50 Torr to about 600 Torr, for example, about 100 Torr to about 300 Torr. The u-GaN layer 110 may be deposited to a thickness of about 1 μm to about 100 μm, and the n-GaN layer 112 may be deposited to a thickness of between about 2 μm and about 140 μm. In one example, the u-GaN/n-GaN layer 110, 112 is deposited to a total thickness of about 4 μm. In some embodiments, the u-GaN layer 110 may be omitted.

Alternatively, an HVPE process may be used to deposit the Group III-nitride layers in an HVPE chamber. In such a case, the HVPE chamber may be configured to provide rapid deposition of GaN material by using HVPE precursor gases, for example, GaCl₃ and NH₃ at a susceptor temperature between about 700° C. to about 1100° C. and a chamber pressure of about 450 Torr. The gallium containing precursor may be generated by flowing chlorine gas at a flow rate between about 20 sccm to about 150 sccm over liquid gallium maintained at a temperature between 700° C. to about 950° C. The liquid gallium may be maintained at a temperature of about 800° C. Ammonia is supplied to the processing chamber at a flow rate within the range between about 6 SLM to about 20 SLM. If desired, the second processing chamber may be cleaned after each u-GaN and n-GaN deposition process, followed by a purge/evacuation step to remove cleaning by-products generated during the cleaning process.

At step 506, an InGaN multi-quantum-well (MQW) active layer 116 is then deposited over the n-GaN layer 112 (FIG. 1) in a third processing chamber, for example, a MOCVD chamber. Precursor gases such as trimethyl gallium (TMG), trimethyl indium (TMI), and NH₃ may be flowed into the third processing chamber along with a H₂ carrier gas flow at a susceptor temperature of from about 700° C. to about 850° C. and a chamber pressure of from about 100 Torr to about 500 Torr. The InGaN MQW active layer 116 may have a thickness of about 750 Å, which may be deposited over a period of about 40 minutes to several hours at a temperature of about 750° C.

If desired, the process recited in step 506 may be performed in the same MOCVD chamber as the processes recited in steps 508-510 without any growth interruption. However, it has been observed that the growth of GaN material at high temperatures may result in severe parasitic deposition of Ga metal and GaN within the MOCVD chamber, especially on chamber components including the showerhead or gas distribution assembly. Gallium rich depositions cause problems due to the nature of gallium itself which acts as a trap, reacting with the gas phase precursors used for deposition of subsequent layers of LED, such as, for example, tri-methyl indium (TMI), tri-methyl aluminum (TMA), n-type dopants such as silane (SiH₄) and disilane (Si₂H₆), and p-type dopants such as Cp₂Mg. InGaN multi-quantum wells (MQW) is the most affected due to Ga—In eutectic formation at favorable conditions within the MOCVD chamber, leading to PL wavelength drift, PL intensity reduction, and device degradation in general. Therefore, embodiments of the present invention adapts “two-split process” using multiple processing chambers for the InGaN MQW active layer 116, the p-AlGaN layer 120, and the p-GaN layer contact 122, so as to minimize or even eliminate cross contamination between different layers, as will be discussed in details below.

At step 508, after deposition of the InGaN MQW active layer 116, a p-AlGaN layer 120 is then deposited over the InGaN MQW active layer 116 (FIG. 1) in a fourth processing chamber such as a MOCVD or HVPE chamber using a MOCVD process or a HVPE process. When the p-AlGaN layer 120 is grown using MOCVD process, precursors such as trimethyl gallium (TMG), trimethyl aluminum (TMA), NH₃ may be provided in a H₂ carrier gas flow at a susceptor temperature of about 1020° C. and a pressure of about 200 Torr. If desired, TMA and TMG precursors may be selected to provide a suitable Al:Ga stoichiometry of the deposited layer. The p-AlGaN layer 120 may have a thickness of about 200 Å-500 Å, which may be deposited in about 5 minutes at a temperature ranging from about 950° C. to about 1020° C. By using two separate chambers to form the InGaN MQW active layer 116 and p-AlGaN layer 120, the growth of the p-type layer and the MQW layer can be separated into different chambers to avoid the Mg—In cross-contaminations. Meanwhile, the system throughput is also increased by eliminating cleaning and adjustment to the process chambers as would otherwise be required if the InGaN and AlGaN layers are formed in the same chamber.

Once the p-AlGaN layer 120 is deposited over the InGaN MQW active layer 116, the process proceeds to step 510. At step 510, a p-GaN contact layer 122 is deposited over the p-AlGaN layer 120 (FIG. 1) in the fourth processing chamber using either MOCVD process or a HVPE process. In embodiments where the MOCVD process is used, precursors such as trimethyl gallium (TMG), NH₃, Cp₂Mg, and N₂ may be flowed into the third processing chamber at a susceptor temperature of 1020° C. and a pressure of about 100 Torr. Alternatively, the p-GaN contact layer 122 may be grown in an ammonia free environment using flows of TMG, Cp₂Mg, and plasma activated N₂ at a susceptor temperature of between about 850° C. and about 1050° C. for around 25 minutes. During formation of the p-GaN contact layer 122, the one or more substrates are heated at a temperature ramp-up rate between about 5° C./second to about 10° C./second. The thickness of the p-GaN contact layer 122 that completes the structure may be about 0.1 μm-0.5 μm or thicker. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl) magnesium (Cp₂Mg or (C₅H₅)₂Mg) for magnesium doping.

### Exemplary Fabricating Methods Using Silicon Substrates

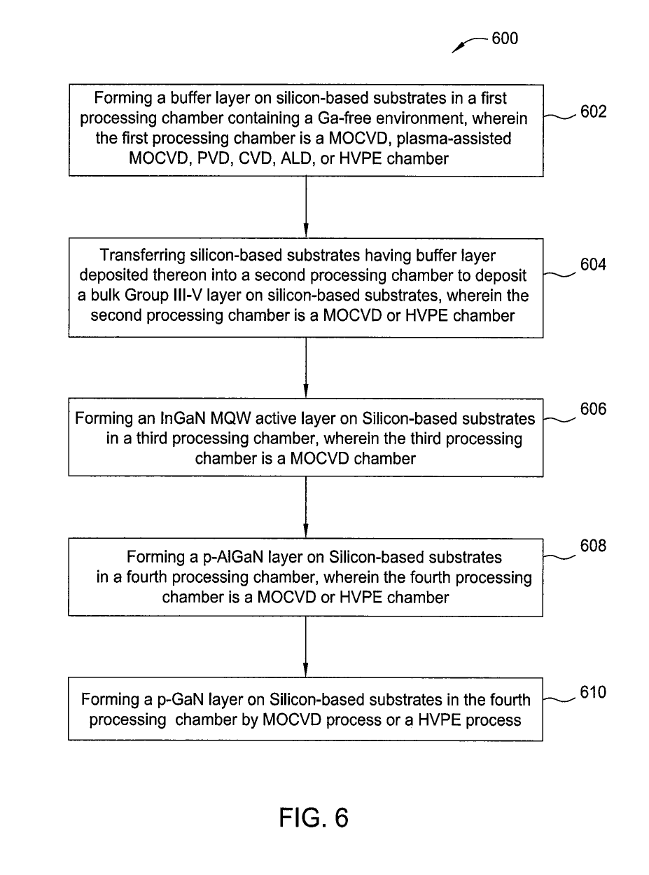

The abovementioned concept using two separate processing chambers to form the buffer layer and the bulk Group III-nitride layers has been found useful when using silicon-based substrates. As discussed previously, while buffer layers using GaN, AlN, AlGaN, InGaN, or InAlGaN have been able to provide a good interface region between the sapphire substrate and Group III-nitride layers deposited thereon, growth of certain buffer layers (particularly GaN buffer layers) on silicon-based substrates may encounter certain problems. For example, the high lattice mismatch between a silicon-based substrate and GaN layer results in a high dislocation density in the GaN layer. In addition, the large difference in the thermal expansion coefficient between GaN and Si induces a large tensile stress in the GaN layer during cooling down from the growth temperature to room temperature, resulting in cracking of the GaN layer. Another problem for the growth of GaN buffer layer on silicon-based substrates is the so-called meltback etching process, created by the formation of a Ga—Si eutectic alloy at the high processing temperatures used during the subsequent u-GaN or n-GaN growth. The interaction of silicon and gallium at the substrate interface, initiates a strong and fast etching reaction that destroys the silicon-based substrate and Group III-nitride epitaxial layers deposited thereon, resulting in non-uniform growth of nitride layers or poor surface morphology. For this reason, GaN buffer layer has been found to be an unfavorable candidate for silicon-based substrates. To overcome these problems, a novel processing sequence 600 as illustrated in FIG. 6 is proposed to provide good film quality of Group III-nitride epitaxial layers formed on the silicon-based substrate. It is contemplated that the number and sequence of the processing steps are not intended to limiting as to the scope of the invention described herein, since one or more steps can be added, deleted and/or reordered without deviating from the basic scope of the invention described herein.

The processing sequence begins at step 602 by forming a buffer layer 108 on one or more silicon-based substrates in a first processing chamber in which a Ga-free environment is provided. In one embodiment, the first processing chamber may be a MOCvD, plasma-assisted MOCVD, or PVD chamber. Similar to the step 502 discussed above, the first processing chamber may be one of multiple processing chambers disposed in a processing system that generally comprises a transfer chamber, two or more processing chambers and a loadlock chamber. Alternatively, the first processing chamber may be a batch processing chamber disposed in an in-line processing system that may or may not have a transfer chamber. In one example of step 602, a buffer layer 108 comprising Al, AlN, or SiN, which is doped or undoped depending upon application, is formed over the substrate surface. In one example, the buffer layer 108 is an AlN material deposited using a PVD process in a PVD chamber. Depositing an AlN buffer layer on the silicon-based substrate in a Ga-free processing chamber avoids the potential Ga—Si eutectic reaction, since either the Ga-based buffer layer is not present at the substrate surface or the Ga-based layer deposition is not performed in the first processing chamber, thus removing the possibility that gallium containing material will migrate to and contaminate the silicon substrate surface.

The AlN buffer layer may be deposited on a silicon-based substrate by reactively sputtering the Al in an argon (Ar) and nitrogen (N₂) gas mixture that is maintained at a reduced pressure, such as an environment maintained at about 0.5 mTorr to several Torr, for example, about 0.5 mTorr to about 300 Torr. In another case, the AlN material may be deposited on the silicon-based substrate by RF and/or DC biasing an aluminum nitride (AlN) target in an argon (Ar), and/or nitrogen (N₂), environment to sputter the AlN material on to the surface of the silicon-based substrate. It is also contemplated that the AlN material may be deposited by evaporating aluminum (Al) in a nitrogen (N₂) rich environment, or even by forming the AlN layer using a CVD method. In various embodiments, the buffer layer 108 is formed to a thickness between 10-800 nm, but the thickness may vary and in some cases it could be up to 0.5-1.0 μm.

Alternatively, the AlN buffer layer may be deposited on the silicon-based substrate using an MOCVD process. In such a case, precursor gases such as trimethyl aluminum (TMA) and NH₃ may be introduced into the first processing chamber at a TMA flow rate between about 0 sccm to about 10 sccm and a NH₃ flow rate between about 0 slm to about 30 slm, and a susceptor temperature of about 500° C. to about 900° C. and a chamber pressure of from about 50 Torr to about 300 Torr to form the AlN buffer layer. It is contemplated that the buffer layer 108 may be formed by CVD, ALD, HVPE, or any other appropriate technique.

In certain applications where a GaN buffer layer is still needed, a passivation layer comprising Al, AlN, or SiN material may be deposited on the surface of the silicon-based substrate followed by the GaN buffer layer. A passivation layer comprising Al, AlN, or SiN material may be deposited, for example, by a conventional physical or chemical vapor deposition as discussed above, to form a continuous passivation layer across the surface of the silicon-based substrate. This passivation layer is believed to provide a good integration between the GaN buffer layer and the silicon-based substrate without suffering from Ga—Si meltback etching problems as discussed above. The passivation layer may have a thickness in the range of about 10 Angstroms to about 6,000 Angstroms, such as about 3500 Angstroms. If the GaN buffer is used with an Al_{X}N_{Y} passivation layer, the Al_{X}N_{Y} passivation layer may be deposited in a first processing chamber (PVD, MOCVD, CVD, or ALD chamber) and the GaN buffer layer and the bulk Group III-nitride layers may be deposited in a second processing chamber (MOCVD or HVPE chamber) to avoid any potential cross contaminations and/or unnecessary cleaning and process adjustments.

At step 604, after deposition of the buffer layer 108, the deposited silicon substrates are transferred into a second processing chamber to deposit bulk Group III-nitride layers over the buffer layer 108 on silicon substrates. The second processing chamber may be a MOCVD or a HVPE processing chamber in which an Al-free environment is provided. As the buffer layer using AlN material was not deposited in this second processing chamber, the subsequent layers are free from potential Al contaminations. The use of a separate processing chamber for deposition of the bulk Group III-nitride layers offers similar advantages as those discussed previously at step 504, such as providing a pure nucleation or growth characteristics for subsequent nitride layers, resulting in better film properties and surface morphology. Meanwhile, the system throughput may be increased by eliminating cleaning and adjustment to the process chambers as would otherwise be required if the buffer layer and bulk Group III-nitride layers are formed in the same chamber.

Similar to step 504, after transferring the substrates into the second processing chamber, bulk Group III-nitride layers, e.g., undoped GaN (u-GaN) layer 110 and n-doped (n-GaN) layer 112 are sequentially deposited on the buffer layer 108 by a MOCVD or HVPE process. Thereafter, an InGaN MQW active layer, p-AlGaN layer, and a p-GaN layer may be sequentially deposited on the bulk Group III-nitride layers, as shown in steps 606, 608, and 610 of FIG. 6. The processing steps described in steps 604, 606, 608, and 610 are generally similar to the process(es) performed in conjunction with step 504, 506, 508, and 510, which are discussed above. Therefore, the individual processing steps will not be re-discussed herein.

While the foregoing is directed to embodiments of the present invention, other and further embodiments of the invention may be devised without departing from the basic scope thereof, and the scope thereof is determined by the claims that follow.

What is claimed is:

1. A method for fabricating a compound nitride structure, comprising:
forming a first group III-nitride layer over two or more substrates in a first processing chamber, wherein the first group III-nitride layer is formed using a metal organic chemical vapor deposition (MOCVD) process, a physical vapor deposition (PVD) process, chemical vapor deposition (CVD) process, or an atomic layer deposition (ALD) process;
transferring the two or more substrates from the first processing chamber to a second processing chamber in a controlled environment; and
forming a second group III-nitride layer on the first group III-nitride layer in the second processing chamber, wherein forming the second group III-nitride layer comprises:
exposing a second group III metal to a hydrogen-free halogen containing gas to form a second precursor; and
delivering the second precursor and a nitrogen source to a surface of each the two or more substrates.

2. The method of claim 1, wherein each of the two or more substrates comprise silicon or silicon carbide.

3. The method of claim 1, wherein the first group III-nitride layer comprises GaN, AlN, AlGaN, InGaN, or InAlGaN.

4. The method of claim 1, wherein forming the first group III-nitride layer over two or more substrates comprises:
delivering one or more process gases through a showerhead having a plurality of gas passages oriented to uniformly deliver the one or more process gases to the two or more silicon containing substrates.

5. The method of claim 1, further comprising:
depositing an InGaN layer over the second group III-nitride layer by a MOCVD process;
depositing a p-doped AlGaN layer over the InGaN layer formed by a MOCVD process or a HVPE process; and
depositing a p-doped GaN layer over the p-doped AlGaN layer by a MOCVD process or a HVPE process.

6. The method of claim 5, wherein the InGaN layer is formed in a third processing chamber, and the depositing the p-doped AlGaN layer and the depositing the p-doped GaN layer are performed in a fourth processing chamber.

7. The method of claim 1, wherein the first processing chamber is a Ga-free environment, and the first group III layer comprises Al, AlN, or SiN.

8. A method for fabricating a compound nitride structure, comprising:
forming a first group III-nitride layer on two or more silicon containing substrates in a first processing chamber, wherein forming the first group III-nitride layer comprises:
delivering one or more process gases through a showerhead having a plurality of gas passages oriented to uniformly deliver the one or more process gases to the two or more silicon containing substrates; and
forming a desired temperature distribution across the two or more silicon containing substrates using a heat source, wherein the two or more silicon containing substrates are disposed between the showerhead and the heat source;
transferring the two or more silicon containing substrates from the first processing chamber to a second processing chamber in a controlled environment; and
forming a second group III-nitride layer on the first group III-nitride layer in the second processing chamber, wherein forming the second group III-nitride layer comprises:
exposing a second group III metal to a hydrogen-free halogen containing gas to form a second precursor; and
forming a second film on the two or more silicon containing substrates by delivering the second precursor and a nitrogen source to a surface of each the two or more silicon containing substrates.

9. The method of claim 8, wherein the first group III-nitride layer comprises GaN, AlN, AlGaN, InGaN, or InAlGaN.

10. The method of claim 8, wherein each of the two or more silicon containing substrates comprise silicon or silicon carbide.

11. The method of claim 8, wherein the first processing chamber is a Ga-free environment, and the first group III layer comprises Al, AlN, or SiN.

12. The method of claim 8, further comprising:
forming a third group III-nitride layer on two or more silicon containing substrates in a third processing chamber, wherein forming the third group III-nitride layer comprises:
delivering a third precursor, a fourth precursor and a nitrogen source gas through a showerhead having a plurality of gas passages oriented to uniformly deliver the one or more process gases to the two or more silicon containing substrates; and
forming a desired temperature distribution across the two or more silicon containing substrates using a heat source, wherein the two or more silicon containing substrates are disposed between the showerhead and the heat source.

13. A method for fabricating a compound nitride structure, comprising:
forming a first group III-nitride layer on two or more silicon containing substrates in a first processing chamber, wherein forming the first group III-nitride layer comprises:
delivering one or more process gases through a showerhead having a plurality of gas passages oriented to uniformly deliver the one or more process gases to the two or more silicon containing substrates; and
forming a desired temperature distribution across the two or more silicon containing substrates using a heat source, wherein the two or more silicon containing substrates are disposed between the showerhead and the heat source;
transferring the two or more silicon containing substrates from the first processing chamber to a second processing chamber in a controlled environment;
forming a second group III-nitride layer on the first group III-nitride layer in the second processing chamber;
transferring the two or more silicon containing substrates from the second processing chamber to a third processing chamber in the controlled environment;
forming a ternary group III-nitride layer over the second group III-nitride layer in the third processing chamber, wherein forming the ternary group III-nitride layer comprises:
delivering a first group III precursor, a second group III precursor and a nitrogen source gas through a showerhead having a plurality of gas passages oriented to uniformly deliver the first group III precursor, the second group III precursor and the nitrogen source gas to the two or more silicon containing substrates; and
forming a desired temperature distribution across the two or more silicon containing substrates using a heat source, wherein the two or more silicon containing substrates are disposed between the showerhead and the heat source;
transferring the two or more silicon containing substrates from the third processing chamber to a fourth processing chamber in the controlled environment;
forming a first doped group III-nitride layer over the ternary group III-nitride layer in the fourth processing chamber, wherein forming the first doped group III-nitride layer comprises:
delivering the first group III precursor and a nitrogen source gas through a showerhead having a plurality of gas passages oriented to uniformly deliver the first group III precursor and the nitrogen source gas to the two or more silicon containing substrates; and
forming a desired temperature distribution across the two or more silicon containing substrates using a heat source, wherein the two or more silicon containing substrates are disposed between the showerhead and the heat source; and
forming a second doped group III-nitride layer on the first doped group III-nitride layer.

14. The method of claim 13, wherein the first group III-nitride layer comprises GaN, AlN, AlGaN, InGaN, or InAlGaN.

15. The method of claim 13, wherein each of the two or more silicon containing substrates comprise silicon or silicon carbide.

16. The method of claim 13, wherein the first processing chamber is a Ga-free environment, and the first group III layer comprises Al, AlN, or SiN.

17. The method of claim 13, wherein the second processing chamber is an Aluminum-free environment.
